(19) United States
(12) Patent Application Publication
(10) Pub. No.: US 2022/0408543 A1
(43) Pub. Date: Dec. 22, 2022

(54) HEATSINK COOLING ARRANGEMENT

(71) Applicant: Vacon Oy, Vaasa (FI)

(72) Inventors: Sami Karhunen, Nordborg (DK); Laura Junttila, Nordborg (DK)

(21) Appl. No.: 17/832,777

(22) Filed: Jun. 6, 2022

(30) Foreign Application Priority Data
Jun. 22, 2021 (DE) 102021116133.9

(51) Int. Cl. H05K 1/02; H05K 7/20

(52) U.S. Cl. CPC H05K 1/021; H05K 7/20418; H05K 7/20454; H05K 2201/066

(57) ABSTRACT

The heatsink cooling arrangement, fitted to cool a semiconductor component, is transferring heat to a backplate heatsink and secures a mechanical stabile assembly of PCBA, encapsulation, heatsink cooling arrangement to a backplate heatsink, which is fast and easy to assemble with usage of few- or no tools.

### CROSS-REFERENCE RELATED TO APPLICATION

This application claims foreign priority benefits under U.S.C. § 119 from German Patent Application No. 10 2021 116 133.9 filed Jun. 22, 2021, the content of which is hereby incorporated by reference in its entirety.

### TECHNICAL FIELD

The present invention relates to a heatsink cooling arrangement that can engage into a shelf or rack holding typical, control- and power electronic circuitries in plural modules to say a power converter which is provided with such heatsink cooling arrangement.

### BACKGROUND

Electronic components are configured by mounting them on Printed Circuit Boards Assemblies (PCBA). Some components e.g. CPU, FPGA, and semiconductor chips will under operation be generating heat to an extend that will require cooling to maintain a long lifetime. The cooling is typical performed by means of heatsinks which conduct heat to a colder area, say surrounding air or backplate. The heatsink is mechanical secured to the semiconductor component which requires cooling and to a rack, chassis, enclosure, encapsulation, frame to both, secure a heat transfer away from the component to a colder section- and to ensure a mechanical stabile connection between parts, in particular robustness against vibrations and mechanical impacts.

The object of this invention is to enable a plural of PCBA modules to be combined into a single compact unit using little space but ensuring a good cooling of said semiconductor components e.g. Central Processor Unit.

### SUMMARY

The present invention was made to offer a solution for a plurality of PCBA modules to be mounted into a single module using little space and each PCBA wasting little space between one another. The processor e.g. CPU on each PCBA would need additional cooling via heat conductive arrangements to say a heatsink backplate. The CPU may during assembly be supplied with heat paste to secure a good heat transfer from CPU to heatsink.

The PCBA can be encapsulated to say IP 54-IEC 60529 standard within an enclosure and still allow connectors and cables to be attached to the circuitry.

Present invention offers an easy assembly of various parts; cooling heatsink arrangement, backplate heatsink, PCBA, encapsulation, to be assembled by using only a few tools e.g. only a screwdriver or no screwdriver and a tube of heat paste. Time spend on assembly is short because usage of only a few vital parts which mostly click into one another.

The object is solved according to the solutions indicated in the claims.

This includes introducing a heatsink cooling arrangement for cooling a semiconductor component, wherein the heatsink cooling arrangement comprises an overlapping flange of the heatsink cooling arrangement adapted to overlap the semiconductor component. The overlapping flange helps to transfer heat from the semiconductor component to the heatsink cooling arrangement and they therefore adapted to be in heat transferring connection.

The overlapping flange of the heatsink cooling arrangement may comprise at least one, preferably a plural number of fill though-holes in the overlapping flange. The fill though-hole is allowing a heat conducting paste/heat pate to be say injected into any gap formed between the overlapping flange and the semiconductor component when the heatsink cooling arrangement is assembled to the encapsulation, PCBA.

The overlapping flange of the heatsink cooling arrangement may comprise an inspection though-hole in the overlapping flange. The inspection though-hole allows during assembly, the inspection of filling heat paste to any gap formed between the overlapping flange and the semiconductor component. The filling may be stopped when the heat paste may become visible via the inspection though-hole.

The overlapping flange of the heatsink cooling arrangement may comprise a through-hole for a screw to be inserted into the overlapping flange and into the encapsulation and lock the heatsink cooling arrangement thigh and secure to the encapsulation. The usage of a screwdriver may be necessary during assembly or disassembly of the items.

The overlapping flange of the heatsink cooling arrangement may comprise a click lock feature to lock the heatsink cooling arrangement 1 thigh and secure to the encapsulation. The advantage may be that no tools is necessary during assembly or disassembly of the items.

The heatsink cooling arrangement may lock to the encapsulation via engaging the click lock feature to encapsulation locking feature. The encapsulation locking feature may be an integrated part of encapsulation. The heatsink cooling arrangement and encapsulation may have a plurality of click lock features. In the figures, there are four click lock features, but the number is not limited to the figures.

The heatsink cooling arrangement may be locked to the backplate heatsink via the backplate locking fin. The locked feature is engaged by sliding locking feature under the locking fin as shown for example in FIG. 9.

The heatsink cooling arrangement may be locked to the backplate heatsink via the screw accommodating feature and a screw not shown in any figures. The heatsink cooling arrangement is locked by mounting a screw into the through hole in the screw accommodating locking feature 1 and into the screw accommodating feature. The screw accommodating feature may have threads in the hole for a screw to be mounted.

A label may be placed onto the overlapping flange. The label may hide any screw, fill through-hole, inspection through-hole. The label may include readable text, barcodes, data matrix code, QR-code, warning sign, logo. On the backside of the label, there may be adhesive for the label to stay onto any surface.

The electrical connector is mounted onto the PCBA, near the edge side. FIG. 5 is an example of the connector's positions, but the position is not limited to FIG. 5. The electrical connector may be mounted to the top- or bottom side, on either of the four edges or any other location e.g. center of the PCBA.

The PCBA is fixated to the encapsulations inside structure. The purpose of the encapsulation is to fixate the PCBA and to protect the electronic circuitry against moisture, dust and the elements, which may have negative impact on the circuitry's function, lifetime, performance. The encapsulation may be chosen to fulfill a certain level of IP protection described in say IEC 60529.

The heatsink cooling arrangement may have a plurality number of utility access through-holes, the number of utility access through holes is not limited to what is show in any figures. The shape and size are not limited to any of the figures. The utility access through-hole may have a variety of functions e.g. to give access to a PCBA mounted connector, give access to a trimmer-potentiometer, cooling air flow to the PCBA, to lock the heatsink cooling arrangement to the backplate heatsink via the backplate locking fin.

The heatsink cooling arrangement may have an overlapping flange which may overlap a semiconductor component when the heatsink cooling arrangement is fully assembled with PCBA and encapsulation. The overlapping flange may not have good thermal contact with the semiconductor component due to a gap between the two surfaces may present. Any presence of an air in the gap may be filled with heat paste during assembly to minimize the gap. Heat paste with good thermal conductivity capabilities may be preferable for the purpose to transfer heat created in the semiconductor component, over to the overlapping flange via the heat paste.

The heat in the overlapping flange may be transferred to the whole heatsink cooling arrangement and to the backplate heatsink when heatsink cooling arrangement is assembled to the heatsink backplate. The overlapping flange may have a plural number of fill through-hole for say allow heat paste to be injected into any gap between the overlapping flange and the semiconductor component.

The backplate heatsink is configured to receive a plural number of heatsink cooling arrangement. The number is not limited to any figures. The plural number of heatsink cooling arrangement may be mounted in a 90° direction as shown in FIG. 8. The heatsink cooling arrangement may be positioned and locked next to one another in a row as the backplate heatsink is configured to receive. The heatsink backplate may be configured to receive and lock a plural number of heatsink cooling arrangement, but the actual number of attached, locked heatsink cooling arrangement may be lower.

The invention is a method for assembling a heat sink in particular as described above. During assembly, the gap between the overlapping flange and the semiconductor component is filled with heat paste. The heat paste may be injected into the gap via the fill through-hole. During filling the heat paste it may be possible to observe via the inspection through-hole when the gap is filled. The heat paste may be visible via the inspection through-hole which may cause the heat paste filling to be stopped.

The filling heat paste may also be made by injecting a predefined amount into the gap. By choosing the method of filling heat paste by a predefined amount, the inspection through-hole may not be present in the overlapping flange.

### BRIEF DESCRIPTION OF THE DRAWINGS

FIG. 1 is a perspective view of the encapsulation with the heatsink cooling arrangement engaged. The label has been removed to show the overlapping flange.

FIG. 2 is a perspective view of the encapsulation with the heatsink cooling arrangement engaged. The label is mounted on the overlapping flange.

FIG. 3 is a perspective view of the heatsink cooling arrangement not mounted to the encapsulation and backplate. Most features of the heatsink cooling arrangement are visible.

FIG. 4 is a perspective view into the semiconductor component. Heatsink cooling arrangement is removed to show the entire semiconductor component mounted to the PCBA.

FIG. 5 Exploded view of the PCBA, heatsink cooling arrangement, encapsulation, all separated.

FIG. 6 Close view of the click locking feature where assembly can be made without using tools. The heatsink cooling arrangement is locked to the encapsulation in this view.

FIG. 7 Close view of the overlapping flange of the heatsink cooling arrangement, with fill hole and inspection hole.

FIG. 8 Perspective view of the heatsink cooling arrangement mounted onto the backplate heatsink. The backplate heatsink may accommodate plural heatsink cooling arrangements.

FIG. 9 Close view of the backplate heatsink with fin feature to accommodate mechanical stabile mounting of the heatsink cooling arrangement to the backplate heatsink.

FIG. 10 Close view of the backplate heatsink with a feature to accommodate a screw mounting of the heatsink cooling arrangement to the backplate heatsink.

FIG. 11 Close view of the heatsink cooling arrangement during assembly, sliding onto the encapsulation. The heatsink cooling arrangement is still in an unlocked position.

FIG. 12 Close view of the overlapping flange of the heatsink cooling arrangement, comprising a click lock feature 20 instead of a through hole 9 to accommodate a screw

### DETAILED DESCRIPTION

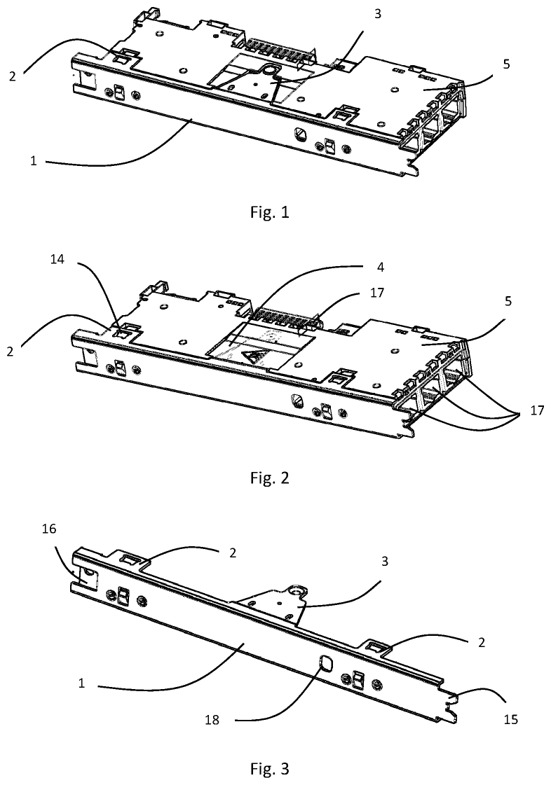

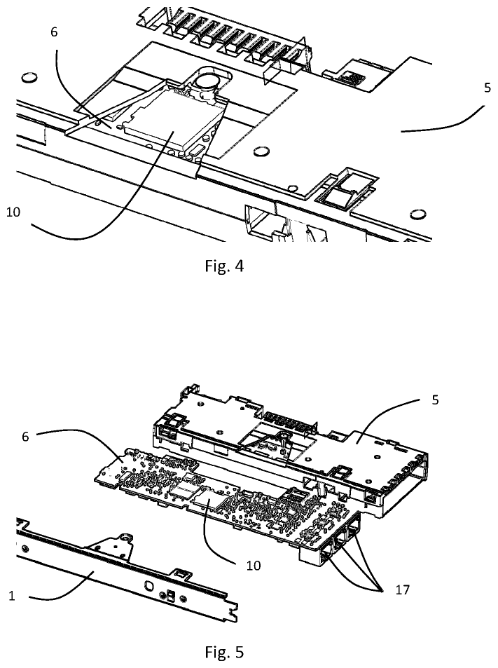

FIG. 1 shows heatsink cooling arrangement 1 for cooling a semiconductor component. The heatsink cooling arrangement 1 comprises an overlapping flange 3 adapted to overlap the not shown semiconductor component. The heatsink cooling arrangement 1 is locked onto an encapsulation 5 by means of a plurality of click lock features 2.

In an embodiment, FIG. 2 is a view of the heatsink cooling arrangement 1 locked onto the encapsulation 5 and the label 4 with e.g. warning signs and readable text, positioned onto the overlapping flange 3. The label 4 may have adhesive on the backside.

In a preferred embodiment, the heatsink cooling arrangement 1 is configured from a plurality of heatsink cooling arrangement 1, members. The heatsink cooling arrangement 1 of FIG. 3 embodies an overlapping flange 3, which is designed to overlap a significant part of a semiconductor component 10 and ensure a good thermal heat transfer from the semiconductor component 10 to the heatsink cooling arrangement 1.

In a preferred embodiment, the heatsink cooling arrangement 1 features a plurality of click lock features 2 which is designed to engage with encapsulating locking feature 14 and lock heatsink cooling arrangement 1 to encapsulation 5, without the usage of tools during assembly. The click lock feature 2, is during assembly slid over the encapsulating locking feature 14 to an engaged locked position, FIG. 6. The locked position of heatsink cooling arrangement 1 to encapsulation 5 is reached when an audible click sound is obtained and or a retraction of heatsink cooling arrangement 1 away from encapsulation 5, is no longer possible.

The heatsink cooling arrangement 1 may embody a plurality of click lock features 2 and encapsulation 5 may embody a similar number of encapsulating locking features 14, but the numbers may also be not equal.

To obtain a locked state of heatsink cooling arrangement 1 with encapsulation 5, the click lock feature 2 is engaged to a locked position with encapsulation locking feature 14, the heatsink cooling arrangement 1 may embody a similar click lock feature 2 on the counter side, to effective lock heatsink cooling arrangement 1 to encapsulation 5. Other solutions the keep the locked position of click locked feature 2 to encapsulating locking feature 14 may be a flange, a design feature of the encapsulation 5 to maintain the lock position of click lock feature 2 to encapsulation locking feature 14.

In a preferred embodiment, the heatsink cooling arrangement 1 may embody a plurality of overlapping flange 3, designed to cool semiconductor components 10 or any type of electronic components which generates heat and need cooling under operations. Lifetime of semiconductor- and electronic components is significantly reduced because of heat. The purpose of overlapping flange 3 is to reduce heat in semiconductor component 10 by transferring heat to a colder area or to the air. To cool a semiconductor component 10, an overlapping flange 3 of heatsink cooling arrangement 1 may transfer heat away from a semiconductor component 10. The heatsink cooling arrangement 1 may typically be made of metal which is an excellent conductor of heat.

The overlapping flange 3 may have any shape and form to suit the form of the semiconductor component 10. The overlapping flange 3 may not fully cover the semiconductor component 10 but still be able to obtain sufficient cooling capabilities and offer long lifetime of the semiconductor component 10.

The overlapping flange 3 may have air pockets between semiconductor component 10. Air is a poor conductor of heat and therefore any air pocket may result in high heat in semiconductor component 10, which isn't transferred over to heatsink cooling arrangement 1. To avoid these air pockets, it is known in the art that heat paste or silicone with heat conductive capabilities may be used as filler in the space between the overlapping flange 3 and semiconductor component 10, to improve the heat transfer.

In a preferred embodiment, not shown in any figures, the overlapping flange 3 may have a click lock feature 20 not a through-hole 9 to accommodate a screw. This feature will avoid the usage of a screwdriver for installing the heatsink cooling arrangement 1 to enclosure 5. Other methods to secure overlapping flange 3 to enclosure 5 may be a tap or indentation in encapsulation 5 to engage with mating part heatsink arrangement 1 and lock the overlapping flange 3 to heatsink cooling arrangement 1.

In another embodiment not shown in any figures, the overlapping flange 3 may not be secured to encapsulation 5, using any type of locking mechanism. The overlapping flange 3 is held in place by the stiffens of the material used in the overlapping flange 3 and by the heat paste in cured form between overlapping flange 3 and semiconductor component 10.

In a preferred embodiment, the heatsink cooling arrangement 1 moreover overlapping flange 3, comprises a through-hole 9 to accommodate a screw. The screw may be any type of fastener, with threads and a screwhead of various length, diameter and or countersunk screwhead or not countersunk plan screwhead, with Philips-flat, posidrive, hex, Torx and similar common screwheads.

The screw secures that the overlapping flange 3 is thigh connected to encapsulation 5 and may also offer a secure locking of heatsink cooling arrangement 1 to encapsulation 5.

Removing the screw may involve, first removing the label 4 and may damage any cured heat paste, filled in the gap between heatsink cooling arrangement 1 and semiconductor component 10. It may be necessary to apply a new label 4 and or apply a new heat paste filling, in the event the screw must be removed and disassembly of the heatsink cooling arrangement 1 from to encapsulation 5 must be made.

To unlock the, click lock feature 2 from encapsulation locking feature 14, a flathead screwdriver may be used. The screwdriver tip is put under the click lock feature 2 and slightly lifting the click lock feature 2 while retracting the heatsink cooling arrangement 1 away from encapsulation 5.

Another method to unlock the, click lock feature 2 from encapsulation locking feature 14 is to push slightly down the encapsulation locking feature 14 while retracting the heatsink cooling arrangement 1 away from encapsulation 5.

In a preferred embodiment, the heatsink cooling arrangement 1, there may be a fill through-hole 7, made for the sole purpose to insert an injection needle and inject heat paste to fill any gap between overlapping flange 3 and semiconductor component 10. The heat paste may be contained in a syringe, a tube of heat paste, a manual- or automated filling station with heat paste and dosed to a known volume.

In a preferred embodiment of the heatsink cooling arrangement 1, there may also be a plurality of inspection through-holes 8. The purpose of this inspection through-hole 8 is to inspect when heat paste is exiting the inspection through-hole 8 during a filling heat paste operation. When heat paste is exiting the inspection through-hole 8, the filling operation may be stopped and thereby accommodate a precise filling heat past operation were heat paste is filled to a required amount necessary to fill the gap between overlapping flange 3 and semiconductor component 10 and not more, excessive over-filling is thereby avoided.

The inspection through-hole 8 is not limited to inspect when heat paste is exiting but may also be used as fill through-hole 7. The fill through-hole 7 is not limited to filling heat paste into but may also be used as inspection through-hole 8. Inspection through-hole 8 may be a plurality of holes and fill though-hole 7 may be a plurality of holes.

In a preferred embodiment, the heatsink cooling arrangement 1 may embody a plurality of utility access through-holes 18. The utility access through-holes 18 may have shapes of- but not limited to, round, square, square with round edges, elliptical shape. The utility access through-hole 18 allows a screwdriver access to say a, PCBA 6 mounted adjustable resistor for trimming and calibration but may also give access to say a PCBA 6 mounted connector 17 or a PCBA 6 mounted switch.

The utility access hole 18 may also have the purpose to lock the heatsink cooling arrangement 1 to backplate heatsink 11 via backplate locking fin 19.

FIG. 9, the utility access hole 18 may not be used to lock the heatsink cooling arrangement 1 to backplate heatsink 11 but solely allow backplate locking fin 19 to enter into a hole and not blocking for a tight connection between heatsink cooling arrangement 1 and backplate heatsink 11.

In a preferred embodiment, the heatsink cooling arrangement 1 may embody a plurality of locking features 15 to secure an easy installation of heatsink cooling arrangement 1 onto backplate heatsink 11 and to secure a tight stabile connection- and for heat transfer, between heatsink cooling arrangement 1 and backplate heatsink 11, which would be little sensitive to mechanical impacts and vibrations. The locking feature 15 is engaged to a locked position when locking feature 15 is slid under backplate locking fin 12, FIG. 9.

In a preferred embodiment, the heatsink cooling arrangement 1 may be shorter in length than shown in FIG. 3—left to right. The shorter length of heatsink cooling arrangement 1, not shown in any figures, may be from screw accommodation locking feature 16 all way to utility access through-hole 18, and utility access through-hole 18 being no longer present. The locking feature 15 of heatsink cooling arrangement 1 would then engage to a locked position with backplate locking fin 19.

In a preferred embodiment, the heatsink cooling arrangement 1 may embody a plurality of screw accommodation locking feature 16 to secure the installation of heatsink cooling arrangement 1 onto backplate heatsink 11 and secure a tight stabile connection for heat transfer between heatsink cooling arrangement 1 and backplate heatsink 11, which would be little sensitive to mechanical impacts and vibrations. The screw used to secure the heatsink cooling arrangement 1 to backplate heatsink 11 moreover to screw accommodation feature 13 may be mounted after the locking feature 15 is slid into a locked position with backplate locking fin 12—FIG. 9, or backplate locking fin 19.

In a preferred embodiment, the backplate heatsink comprising a plurality of screw accommodation feature 13 and a plurality of backplate locking fin 12, may hold an equal number of heatsink cooling arrangement 1, but the number of heatsink cooling arrangement 1 held, may also be lower.

In a preferred embodiment, the backplate heatsink comprising a plurality of screw accommodation feature 13 and a plurality of backplate locking fin 19, may hold an equal number of heatsink cooling arrangement 1, but the number of heatsink cooling arrangement 1 held, may also be lower.

In a preferred embodiment, the PCBA 6 holds the electronic circuitry which may typically be low power electronic components of say semiconductors as active components and say passive components. The PCBA 6 may have to meet certain requirements for encapsulations, e.g. IP 54 which may be obtain with encapsulating the PCBA 6.

The PCBA 6 embodies a semiconductor component 10 which during operation generate heat to an extend that may need addition cooling.

The PCBA 6 may have any type of active and passive components e.g. trimmer-resistors, connectors 17 which must be accessed through say the encapsulation 5. PCBA 6 may also embody a semiconductor component 10 which requirements to be connected to say a heatsink cooling arrangement 1 for the purpose of cooling the semiconductor component 10. The semiconductor component 10 is not limited to-, but may be any type of electronic component, e.g. resistors, capacitors, inductors.

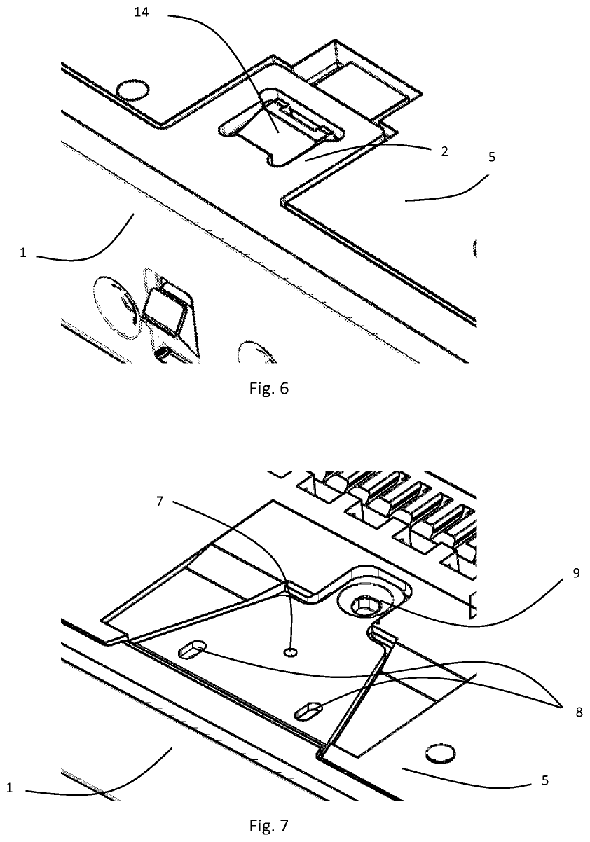

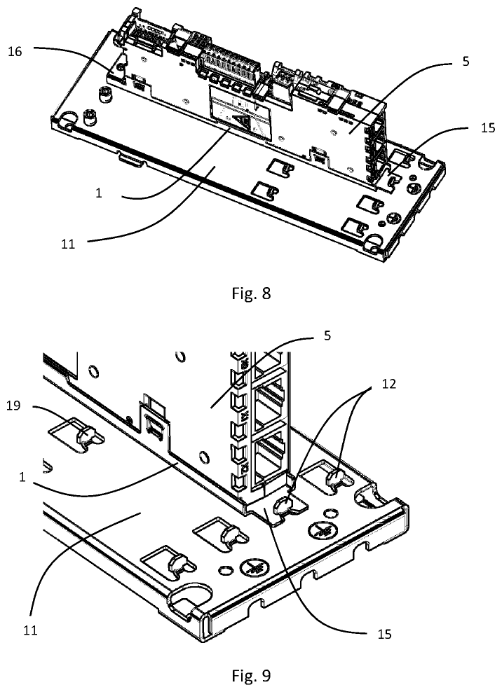

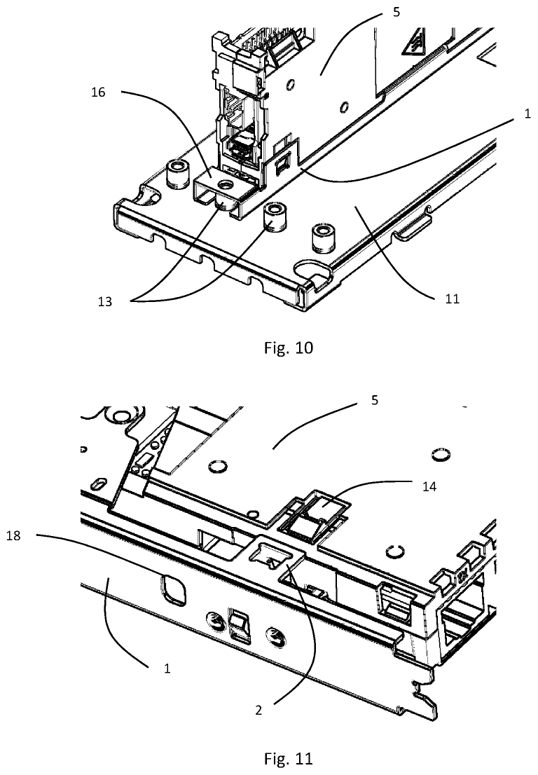

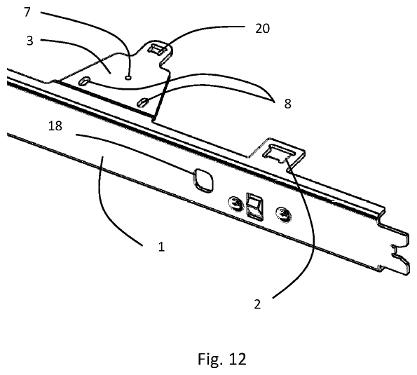

In a preferred embodiment connector 17 are placed on edges of the PCBA as seen in FIG. 5. This PCBA 6 edge location of the connectors 17, ensures mating plugs can be connected and disconnected with ease.

In a preferred embodiment, the encapsulation 5 is designed with openings to meet IP xx encapsulating requirements and to fixate and hold the PCBA inside. The material may typically be molded plastic. Plastic material is chosen from a range of preferred parameter e.g. temperature, price, robustness, color, quantity.

The encapsulation 5 comprises an opening for a heatsink cooling arrangement 1, moreover an overlapping flange 3 to gain access to a semiconductor component 10 for the purpose of transferring heat from semiconductor component 10 to heatsink cooling arrangement 1.

In a preferred embodiment the encapsulation 5 having a plurality of encapsulating locking features 14, which may be molded into the say plastic. The encapsulating locking features 14 can be pressed to engage and disengage with mating part click lock features 2.

The overlapping flange 3 may be a plural number integrated with the heatsink cooling arrangement 1. The number is not limited to any figures.

The fill though-hole 7 may be a plural number not limited to any figures. The inspection though-hole may be a plural number not limited to any figures. The semiconductor component 10 may be a plural number not limited to any figures. The connector 17 may be a plural number not limited to any figures.

The invention is not limited to heat paste filled in the gap between overlapping flange 3 and semiconductor component 10 but may also be no usage of any heat paste. There may be a physical contact between overlapping flange 3 and semiconductor component 10 which may allow thermal transfer of heat without the usage of heat paste. The no usage of heat paste may also eliminate the need for any fill though hole 7, inspection through-hole 8, not shown in any figures.

While the present disclosure has been illustrated and described with respect to a particular embodiment thereof, it should be appreciated by those of ordinary skill in the art that various modifications to this disclosure may be made without departing from the spirit and scope of the present disclosure.

1. A heatsink cooling arrangement for cooling a semiconductor component wherein the heatsink cooling arrangement comprises an overlapping flange adapted to overlap a semiconductor component.

2. The heatsink cooling arrangement according to claim 1, wherein the overlapping flange of the heatsink cooling arrangement comprises a fill though-hole in the overlapping flange adapted for filling heat paste between the overlapping flange and the semiconductor component.

3. The heatsink cooling arrangement according to claim 1, wherein the overlapping flange of the heatsink cooling arrangement comprises an inspection through-hole in the overlapping flange adapted for inspecting when heat paste filled between the overlapping flange and the semiconductor component is accomplished and heat paste is visible in the inspection through-hole.

4. The heatsink cooling arrangement according to claim 1, wherein the overlapping flange of the heatsink cooling arrangement comprises a through-hole adapted to accommodate a screw to lock the overlapping flange to an encapsulation.

5. The heatsink cooling arrangement according to claim 1, wherein the overlapping flange may lock to the encapsulation wherein the overlapping flange of the heatsink cooling arrangement comprises a click lock feature.

6. The heatsink cooling arrangement according to claim 1, wherein the heatsink cooling arrangement may lock to the encapsulation via an encapsulation locking feature wherein the heatsink cooling arrangement comprises a click lock feature.

7. The heatsink cooling arrangement according to claim 1, wherein the heatsink cooling arrangement is slid to the mechanical locked position to a backplate heatsink via a backplate locking fin, wherein the heatsink cooling arrangement comprises a locking feature.

8. The heatsink cooling arrangement according to claim 1, wherein the heatsink cooling arrangement is mechanical locked to the backplate heatsink via a screw accommodating feature, wherein the heatsink cooling arrangement comprises a screw accommodation locking feature.

9. The heatsink cooling arrangement according to claim 1, wherein a label is placed onto the overlapping flange.

10. The heatsink cooling arrangement according to claim 1, wherein an electrical connector are located on any side of a PCBA.

11. The heatsink cooling arrangement according to claim 1, wherein the PCBA is fixated to the encapsulation and isolated inside the encapsulation to keep dust and moisture away from the PCBA.

12. The heatsink cooling arrangement according to claim 1, wherein the heatsink cooling arrangement comprises a utility access through-hole.

13. The heatsink cooling arrangement according to claim 1, wherein it is adapted to connect to the semiconductor component such that the overlapping flange is transferring heat away from the semiconductor component and such that a gap exists between the overlapping flange and the semiconductor component which gap is adapted to be filled with heat paste via the fill though-hole.

14. The heatsink cooling arrangement according to claim 7, wherein a plurality of the heatsink cooling arrangement is locked to the backplate heatsink.

15. A method for assembling the heatsink cooling arrangement according to claim 1 to a semiconductor component, wherein the gap between the overlapping flange and the semiconductor component is configured to be filled with heat paste via fill through-hole.
